(19) United States
(12) Patent Application Publication
(10) Pub. No.: US 2026/0211318 A1
(43) Pub. Date: Jul. 23, 2026

(54) Resist and Process for Dry Positive Tone Electron Beam Lithography

(71) Applicant: California Institute of Technology, Pasadena, CA (US)

(72) Inventors: Axel Scherer, Barnard, VT (US); Richard D. Smith, Pasadena, CA (US)

(21) Appl. No.: 19/453,338

(22) Filed: Jan. 20, 2026

Related U.S. Application Data
(60) Provisional application No. 63/748,381, filed on Jan. 22, 2025.

(51) Int. Cl. G03F 7/00; G03F 7/20; G03F 7/42

(52) U.S. Cl. CPC G03F 7/0035; G03F 7/2037; G03F 7/42

(57) ABSTRACT

A method for lithographically patterning a substrate with a particle beam is fully compatible with a vacuum environment and positive tone development. The process includes physical vapor-depositing a resist layer comprising an organic material, such as myo-inositol, onto the substrate. The resist layer is then subjected to electron beam exposure to define a pattern. Subsequently, the exposed resist layer is thermally developed by heating the layer to an intermediate temperature, causing the exposed regions to be removed via evaporation while leaving the unexposed regions intact. This dry development process, which can optionally occur simultaneously with exposure, enables high-resolution pattern transfer and allows the entire lithography sequence to be performed without breaking vacuum, thereby reducing contamination and increasing microfabrication throughput.

### CROSS REFERENCE TO RELATED APPLICATIONS

The present application claims priority to US provisional patent application Ser. No. 63/748,381 entitled “Resist and Process for Dry Positive Tone Electron Beam Lithography”, filed on Jan. 22, 2025, the disclosure of which is incorporated herein by reference in its entirety.

### TECHNICAL FIELD

The present disclosure relates generally to microfabrication techniques and lithography. More specifically, it relates to resist materials and processes for dry positive tone electron beam lithography, particularly for vacuum-compatible deposition, exposure, and development to enable high-resolution patterning without wet chemistry, and methods for their implementation in fabricating microstructures.

### BACKGROUND

Lithographic pattern definition is a relevant aspect of microfabrication. The most common processes utilize ultraviolet (UV) light exposure through a mask to induce a chemical change in a photoresist. This chemical change allows for the selective removal of either the exposed resist (positive resist) or the unexposed regions (negative resist). As feature sizes decrease, the wavelength of the exposing radiation must be reduced to avoid diffraction limitations on the desired feature size. Consequently, significant effort has been expended in the development of higher resolution photolithography systems, with the complexity of the lithographic process increasing substantially at extreme ultraviolet (EUV) exposing wavelengths.

An alternative resist patterning technique employs charged energetic particles, most frequently electrons, guided by electromagnetic fields to produce features in electron-sensitive resists. Such techniques offer higher resolutions and are generally not limited by diffraction in the same manner as optical lithography, although other practical factors apply. Electron beam lithography is frequently used for mask making, as well as small-scale prototyping and research, because the throughput of e-beam writing instruments is typically lower than that of projection photolithography. Various approaches, such as multi-beam electron beam technologies and shaped beam lithography, have been employed to increase throughput.

However, all electron beam lithography approaches generally require the sample to be in a vacuum environment, as ambient gas molecules deflect the guided energetic particles. This requirement presents a significant challenge because other parts of the fabrication sequence, and particularly the pattern-defining development sequence, are typically wet processes. In standard workflows, resist deposition and development are performed using wet chemistry, whereas the exposure is performed in a vacuum. The delay and potential for contamination resulting from repeatedly venting and pumping down wafers creates a basic conflict with the desire for a high-throughput and competitive fabrication process for high-volume integrated circuit manufacturing.

Recently, novel negative resist processes have been developed in which the resist is vapor-deposited, and the unexposed regions can be re-evaporated. These processes can be performed entirely in a vacuum environment, leading to a simpler process flow. Typically, these new resists involve organometallic compounds that can be sublimed and, after exposure, are converted into more stable metal-based compounds. However, a similar positive resist technology that is compatible with vacuum resist deposition and processing remains elusive. As other parts of the fabrication sequence, such as plasma etching, are increasingly performed in vacuum, the lack of a compatible positive tone process represents a gap in current capabilities.

Therefore, there is a need for a positive tone electron beam resist and processing method that is fully compatible with vacuum environments, enabling deposition, exposure, and development to occur without breaking vacuum, thereby reducing contamination risks and improving throughput in microfabrication.

### SUMMARY

The present disclosure describes a process for depositing, exposing, and developing a positive tone electron beam resist that facilitates a vacuum-compatible workflow. The resist layer is deposited via thermal vapor-deposition by heating a source material to form a stable thin film. For instance, the source material may be heated to temperatures exceeding 200° C. This thin film is sensitive to electron beam exposure, resulting in a positive tone functionality as the exposed regions are removed during a thermal development process.

In this dry process, electron beam exposed regions of the resist are selectively removed by heating the layer to a moderate temperature (e.g., approximately 150° C.), which is generally lower than the temperature used for deposition. As a result, the non-exposed material is maintained in place, and the exposed resist is evaporated. After a subsequent pattern transfer step, the unexposed regions may be removed, for example, by oxygen plasma stripping.

An aspect of the disclosed process is that the entire positive tone sequence can be performed in a vacuum environment without exposure to the atmosphere. Consequently, processing and lithography can be performed without the necessity of removing the workpiece from the vacuum system, thereby reducing contamination and increasing throughput by simplifying the process flow.

According to a first aspect of the present disclosure, a process for lithographically patterning a substrate in a positive polarity is disclosed, the process comprising: (a) vapor-depositing a resist layer onto the substrate; (b) exposing at least a portion of the resist layer with a particle beam to define a pattern, thereby creating exposed regions and unexposed regions in the resist layer; (c) thermally developing the exposed regions of the resist layer by heating the layer to a temperature and for a duration that causes the exposed regions to be removed via evaporation, thereby defining the pattern in the resist layer by retaining the unexposed regions; (d) transferring the defined pattern from the resist layer into the substrate; and (e) stripping the remaining unexposed regions of the resist layer using a chemical or thermal process, the stripping occurring after the pattern transferring step (d).

According to a second aspect of the present disclosure, a process for lithographically patterning a substrate in a positive polarity is disclosed, the process comprising: (a) physically vapor-depositing a resist layer onto the substrate; (b) exposing at least a portion of the resist layer with a particle beam to define a pattern while simultaneously heating the resist layer to a temperature that causes material in exposed regions of the resist layer to leave the exposed regions via evaporation, thereby defining the pattern in the resist layer by retaining unexposed regions; (c) transferring the defined pattern from the resist layer into the substrate; and (d) stripping the remaining unexposed regions of the resist layer using a chemical or thermal process, the stripping occurring after the pattern transferring step (c).

According to a third aspect of the present disclosure, a process for lithographically patterning a substrate in a positive polarity is disclosed, the process comprising: (a) vapor-depositing a resist layer onto the substrate; (b) exposing at least a portion of the resist layer with a particle beam to define a pattern, thereby creating exposed regions and unexposed regions in the resist layer; (c) developing the exposed regions of the resist layer using a solvent that selectively dissolves the exposed regions while substantially maintaining the unexposed regions, thereby defining the pattern in the resist layer; (d) transferring the defined pattern from the resist layer into the substrate; and (e) stripping the remaining unexposed regions of the resist layer using a chemical or thermal process, the stripping occurring after the pattern transferring step (d).

According to a fourth aspect of the present disclosure, a structure is described, comprising: a substrate; and a resist layer disposed on the substrate, wherein the resist layer comprises an organic material formed by vapor-deposition, and the resist layer is configured to chemically or structurally modify in response to particle beam exposure such that exposed regions of the resist layer are removable by thermal development to define a positive tone pattern.

According to a fifth aspect of the present disclosure, a structure is described, comprising: a substrate; and a patterned resist layer disposed on the substrate, wherein the patterned resist layer comprises unexposed regions of an organic material formed by physical vapor-deposition, and wherein the patterned resist layer includes openings corresponding to regions removed by thermal evaporation following a particle beam exposure.

### BRIEF DESCRIPTION OF THE FIGURES

FIG. 1 shows a vacuum deposition system, according to an embodiment of the present disclosure.

FIG. 2 shows the chemical structures of Trehalose, Sorbitol, Glucose, and Myo-inositol.

FIG. 3 shows a schematic of exposure and development of a positive electron beam resist, according to an embodiment of the present disclosure.

FIG. 4 shows a schematic of a vacuum development system, according to an embodiment of the present disclosure.

FIG. 5 shows electron beam-written patterns in myo-inositol etched into an underlying platinum layer by argon ion milling.

FIG. 6 shows a schematic of pattern transfer using a hard mask, according to an embodiment of the present disclosure.

FIG. 7 shows 100 nm features fabricated by electron beam lithography with 200nm vapor-deposited inositol resist, development by heating to 150° C. and ion milling through a platinum thin film.

FIGS. 8A-8C show flowcharts of exemplary process flows according to embodiments of the present disclosure.

### DETAILED DESCRIPTION

The process described herein enables the generation of high-resolution patterns in a vacuum-compatible positive tone resist deposition, exposure, and development process, followed by pattern transfer. Generally, the resist described here is deposited by thermal vapor-deposition, exposed with electrons, thermally developed in vacuum, and used for an etching or deposition process, followed by an oxygen plasma resist removal process.

### Selection of Resist Material for Vacuum Deposition

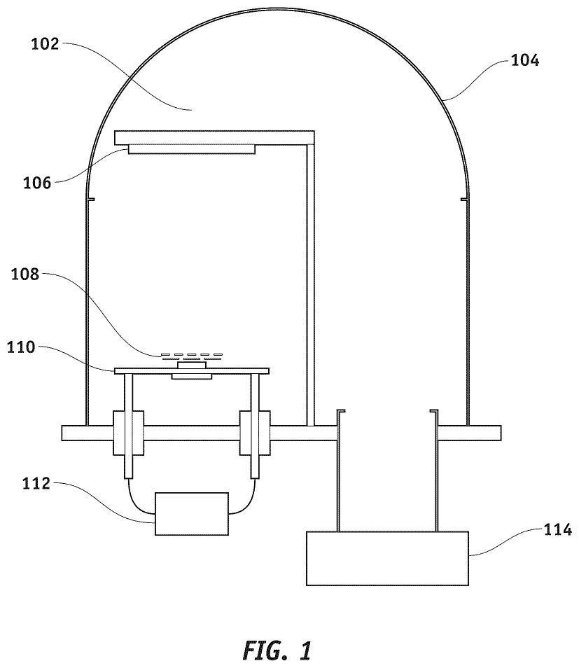

The disclosed process involves the physical vapor-deposition of the resist material in a vacuum deposition system. FIG. 1 shows a vacuum deposition system, according to an embodiment of the present disclosure. The system includes a vacuum system 102 and a vacuum enclosure 104. A substrate 106 is positioned within the vacuum enclosure 104. The resist material is contained within a resistively heated boat 110 with organic resist, which serves as the evaporation source. A power supply 112 for resistive heating is electrically connected to the boat 110 to provide the energy necessary to heat the resist material for thermal vapor-deposition. A baffle 108, implemented to avoid spitting, is positioned over the boat 110 to help ensure uniform film deposition by preventing non-uniform deposition that can result from material spitting. A high vacuum pump 114 is connected to the vacuum enclosure 104 to maintain the low-pressure environment necessary for the physical vapor-deposition process.

For complex organic molecules, sputter deposition would likely lead to significant degradation. Not all molecules can retain their properties during evaporation and may instead undergo thermal degradation. The products of this deterioration may be volatile but may not have the same desired properties of the initial source material. Selection of an electron-sensitive material that can be suitably evaporated, deposited, and further processed is an aspect of the disclosed teachings.

According to the teachings of the present disclosure, the volatilization process may be a combination of sublimation and evaporation, depending on the source of the material and environmental conditions. In the case of thermal evaporation, prevention of spitting of the material is important to avoid non-uniform deposition. Methods to avoid such spitting include the use of baffles (e.g., baffle 108 in FIG. 1) or gratings over the evaporation source.

When selecting the material and deposition process for high-resolution organic resists, it is also important to consider its microstructure, as that can limit the ultimate resolution. This microstructure can be affected by the rate of deposition and the temperature of the substrate 106 of FIG. 1. These conditions affect the extent to which the absorbed vapor molecules migrate on the surface and typically follow a growth-zone model as known to those familiar in the art of inorganic physical vapor-deposition. Materials deposited at temperatures far below their melting point and at relatively high rates are unlikely to have equilibrium structures approaching an ideal crystal of the material.

The stability of the film microstructure will also be affected by its glass transition temperature, which is frequently correlated with the melting temperature. A higher glass transition temperature reduces the extent to which component molecules migrate, as known to those familiar to the art of resist design. Materials with a glass transition temperature near ambient conditions will generally have less structural stability than those with temperatures well above the ambient process temperatures. The glass transition temperature can also be affected by the presence of other materials, as in the case of water or humidity with hygroscopic materials. The presence of water or humidity can significantly reduce the glass transition temperature and material stability, and selecting a material that is structurally stable throughout the conditions during a fabrication process is essential. Stability is sometimes also very desirable between processing steps in standard environments, as this enables batch processing.

Examples of an unstable materials include evaporated glucose and trehalose, aldehyde containing molecules that brown within the boat and result in limited deposition onto the substrate. These examples demonstrate the importance of thermal stability in the choice of organic materials to be thermally evaporated. Sorbitol, a six-carbon, straight chain sugar alcohol, evaporates without substantial residue in the source, but results in films that strongly migrate and crystallize under ambient conditions. To avoid these problems, it is important to choose an organic material with a high melting point as well as a high glass transition temperature, which for sorbitol is below ambient temperatures and substantially reduced in ambient humidity.

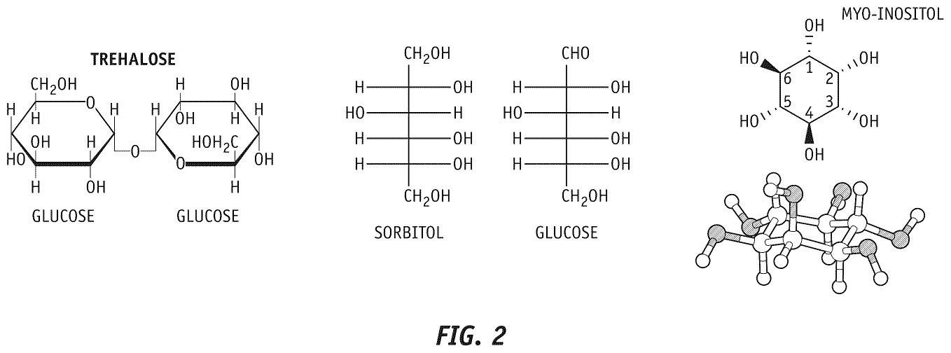

FIG. 2 shows the chemical structures of Trehalose, Sorbitol, Glucose, and Myo-inositol. Isomers of inositol, such as myo-inositol, are favorable organic resist candidates with high melting points, but most of them are very expensive and only available in limited quantities. Fortunately, myo-inositol is the exception, being inexpensive and commercially available, and was therefore selected as a good example of a vacuum-processable positive organic resist material.

Generally, such small molecules have likely not been investigated due to their relatively poor etch resistance (low C ratio, i.e. carbon content) and risk of crystallization. Other small molecule positive resists typically utilize more resistant aromatic moieties and highly asymmetric, poorly packing structures. Aldose sugars (e.g., glucose) thermally degrade before practical evaporation occurs. Linear sugar alcohols have much lower glass transition temperatures. Pentaerythritol was initially tested; it appeared to have a marginally higher crystallization rate, though it is a reasonable candidate for further investigation. A fully symmetric cyclohexanol, scyllo-inositol, has higher temperature phase properties, though it may have worse crystallization resistance due to the higher symmetry. Benzene-hexol would likely have higher etch resistance as an aromatic compound. Replacement with other moieties such as acid or amine groups for ion coordination linkages may be possible. Thermally stable linkages of a linear sugar alcohol may result in the desired amorphous glass layer In addition to structural stability, an electron beam resist must also show a favorable response to electron beams, as this is necessary for sensitive patterning. During a positive lithographic process, the exposed regions must become easier to remove than adjacent unexposed regions. When exposing a myo-inositol film to an electron beam, we observe structural changes with what appear to be gas pockets forming under the films and foam-like expansion of the film. Eventually, these changes that are visible in an electron microscope, stop. One basis for the exposure effects on the layer may be the breaking of bonds or scission in the organic molecules. Such scission leads to smaller molecules, typically with a higher vapor pressure and solvent solubility relative to the initial large polymer. A practical consideration for such an exposure-induced effect is that the molecules may be able to diffuse through the unexposed film and additionally act as a plasticizer for the film, changing the glass transition and thermal properties. Another benefit to the evaporative deposition of an organic resists is that the inherent purification through vapor fractioning or distillation reduces the likelihood of impurities included into the film that could change its properties.

### Resist Development in Solvents

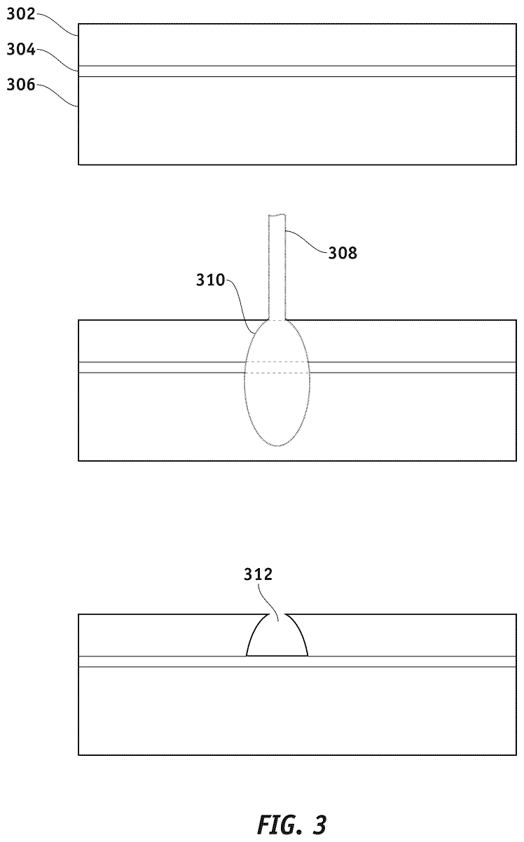

To demonstrate an example of a vacuum deposited organic positive resist material and process, myo-inositol films were exposed and subsequently developed by both dry (vacuum) and wet processes. FIG. 3 shows a schematic of exposure and development of a positive electron beam resist, according to an embodiment of the present disclosure. The process begins with a layer structure comprising a substrate 306, a hard mask 304 disposed on the substrate 306, and an electron beam resist 302 disposed on the hard mask 304. During the exposure step, an electron beam 308 is directed onto the electron beam resist 302, creating an electron interaction volume 310 where the properties of the resist are modified. Subsequently, a development step is performed wherein the exposed resist is removed selectively 312, creating a pattern in the resist layer while leaving the unexposed regions intact.

According to the teachings of some embodiments of the present disclosure, as an alternative to vacuum resist development, a solvent-based process may be used to preferably remove the exposed regions. Solvents that do not affect the myo-inositol layer as well as solvents that dissolved the layer were compared. All the solvents used were not intentionally dehydrated which may affect hygroscopic solvents. Solvents that had no macroscopic effect on an unexposed myo-inositol layer within 30 seconds include hexane, cyclohexane, xylenes, toluene, tetrahydrofuran, ethanol, isopropyl alcohol, butyl alcohol, benzyl alcohol, acetone, propylene glycol methyl ether acetate, chloroform and methylene chloride. A caveat is that humidity from the air or water in the solvent can affect the layer. Much like other sugar alcohols, myo-inositol is highly water soluble, even when unexposed.

Solvents that exhibit strong evaporative cooling in a humid atmosphere, such as acetone, can cause water condensation onto the substrate during drying, and this water in turn can dissolve the myo-inositol. These and other solvents do not substantially dissolve the layer when still submerged and viewed through a transparent vial. This condensation effect can be mitigated by using dry solvents, transitioning from a highly cooling solvent to one less so (e.g. isopropanol), the use of heated vapor drying systems or the use of water-free drying gasses and/or a dry environment (e.g. N2). Polar, non-protic solvents such as dimethylacetamide, dimethylformamide, n-methyl-2-pyrrolidone and dimethyl sulfoxide were able to controllably dissolve the layer, with dimethyl sulfoxide dissolving through 200 nm of myo-inositol in less than 30 seconds, and dimethylacetamide removing approximately 50 nm. Glycerol and ethylene glycol both swelled and dissolved the layer causing some delamination. Methanol appeared to roughen and slightly etch the layer. Methanol, ethylene glycol and glycerol can be considered shorter forms of straight chain sugar alcohols, and the likely porous microstructure enables these solvents to rapidly permeate the bulk of the material. The development rate can be controlled by dilution with a non-interacting solvent, and the selectivity of the developer is optimized by maximizing the differential solubility of the exposed versus unexposed regions. Although fully dry processing is a preferred utilization, it is possible to spin-coat the material out of water and develop it with dry, diluted aprotic polar solvents. Further, the resist layer can be easily stripped by water. Though it can recrystallize due to ambient humidity, exposure to short periods of ambient conditions between vacuum processing and dry storage have not severely degraded the properties, which is important for simplifying and making accessible scientific investigations and process development without access to cluster tooling.

### Resist Development in Vacuum

Myo-inositol is a promising new positive resist that can be thermally evaporated at 215° C. without degradation and forms hard, adherent films. Upon electron beam irradiation, volatile species are apparently formed and subsequent heating to 150° C. leads to clearing of these in exposed regions. Although sugar alcohols can crystallize, their strong intermolecular hydrogen bonding has been reported to cause supercooling into amorphous states. Although the reported glass transition temperature is well above typical processing temperatures, water is known to lower this temperature. This risk of crystallization and reduction in glass transition temperature can be avoided by maintaining the entire process in an N2 or vacuum environment.

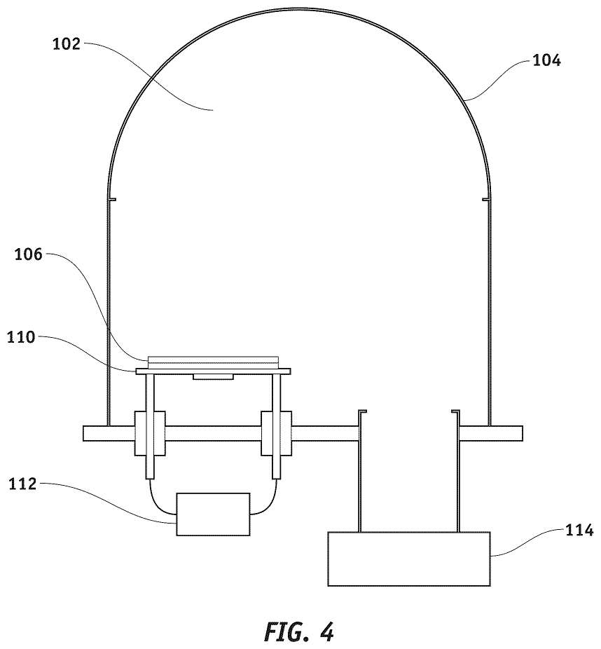

Thermal development of an exposed myo-inositol layer enables fully dry processing. FIG. 4 shows a schematic of a vacuum development system, according to an embodiment of the present disclosure. The system shares the vacuum infrastructure described in FIG. 1, including a vacuum system 102, a vacuum enclosure 104, and a high vacuum pump 114 to maintain the necessary low-pressure environment. A resist coated substrate 106 is positioned within the enclosure. Unlike the deposition process shown in FIG. 1, where the source material in the boat is heated to evaporate, FIG. 4 illustrates a configuration used for thermal development where the resist layer itself is subjected to heat. While the resistively heated boat 110 and power supply 112 are depicted, indicating that the same chamber or a similar configuration may be used, the primary operation in this stage involves heating the substrate or the environment to a specific development temperature to facilitate the sublimation of the exposed resist regions.

Below a threshold temperature, no changes are observed over a practical time period. Above a higher temperature, microstructure changes and sublimation loss of unexposed regions can rapidly evaporate the entire organic film. An optimized dry development process utilizes an intermediate temperature where the exposed regions are cleared but minimal changes occur in the unexposed regions for maximum resist contrast. For unexposed myo-inositol coated substrates in an ambient environment: below 125° C., a myo-inositol layer does not appear to macroscopically change over 15 minutes. At 150° C. the surface appears rougher after 15 minutes. At 175° C., during the 15 minutes the edges of the substrate appear to thin and lose the deposited layer to sublimation. At 200° C. the layer rapidly roughens everywhere within 1 minute and disappears after 15 minutes from the edges inward.

For electron-beam exposed patterns, features became visible by 1 minute. At 200° C. a pattern was visible after 2 minutes, but the unexposed areas had substantially more roughness. After 1 minute at 150° C., small structures are visible in a microscope with some roughening discernible. Using lower temperatures such as 125° C. and 100° C. can also clear patterns with longer times and larger doses, but thinner resulting features. In a preferred embodiment, myo-inositol is used as the resist layer and is preferably evaporated at a rate of approximately 1 nm/s. The layer is exposed with a dose between 1 nC/cm and 30 nC/cm, preferably of 10 nC/cm. The exposed layer is developed with a temperature preferably between 75° C. and 150° C., more preferably at 150° C. for a duration preferably of between 1 to 10 minutes. Finally, the resist layer may be stripped by high temperature exposure, preferentially above 200° C., and/or oxygen plasma exposure. There are pattern tradeoffs among development time, induced roughness, pattern stability and feature size. Relative to solvent processing, thermal processing is typically a less linear process where the exposed regions are closer to either fully developing to the substrate or not at all, whereas solvent development typically etches progressively into the surface. As expected, increasing the dose beyond the optimal range also increases line thickness and blurs the pattern.

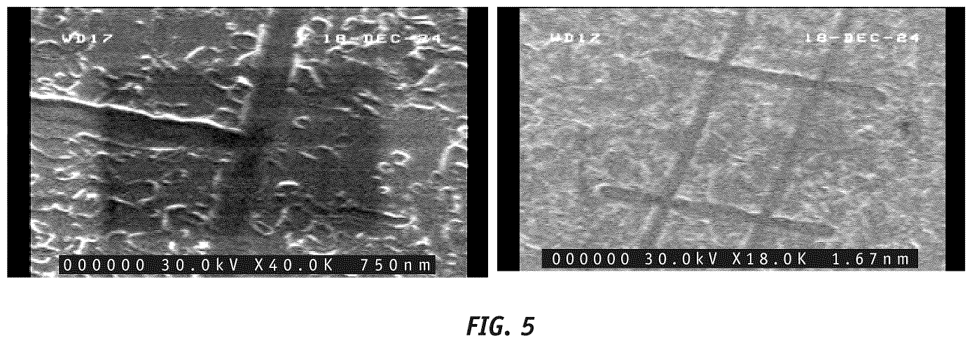

FIG. 5 shows electron beam-written patterns in myo-inositol etched into an underlying platinum layer by argon ion milling. The images demonstrate the result of the process where the patterns are defined and transferred.

The vacuum compatibility of the thermal development process also enables simultaneous exposure and development. The substrate may be heated during the exposure process such that material in the exposed regions immediately leaves the exposed region. This removes a process step and also reduces the diffusion of molecules from the exposed regions into unexposed regions of the resist. During dry development, the substrate may be heated by resistive, thermoelectric, infrared radiation, focused laser beam or any other means as known to those familiar in the art. The substrate should be heated to a temperature and for a duration that increases the rate of the development but does not cause molecules in the unexposed regions to migrate. Ambient humidity in a vacuum environment limits the extent that water can influence the glass transition temperature. Heating during exposure may take advantage of the relatively high energy state of molecules of the film while impacted by the electron beam. This higher energy enables volatilization at a lower temperature, reducing the possibility of structural changes in unexposed film areas.

### Post-exposure Processing With the Developed Positive Resist Mask

In accordance with further teachings of the present disclosure, after development, the patterned film may be used as a mask to transfer the pattern into a substrate. Plasma etching processes are particularly favorable as they do not expose the resist to wet chemistry or exposure to water or humidity. A hard mask material may be deposited before the resist layer, and the pattern of the resist layer can be transferred into this relatively thin hard mask layer. Pattern transfer selectivity into the substrate can be improved with such a hard mask, as known to practitioners of the art.

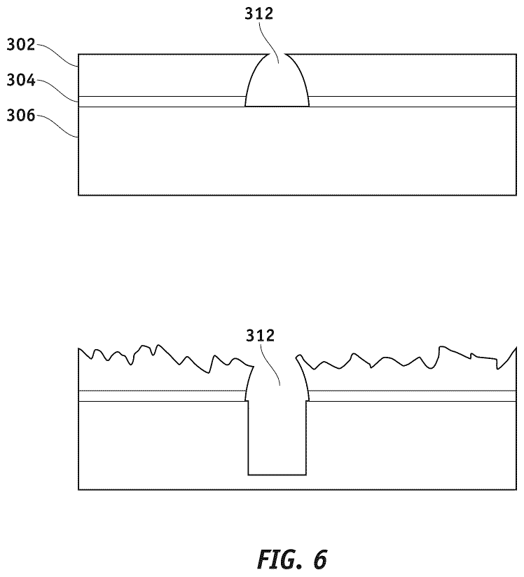

FIG. 6 shows a schematic of pattern transfer using a hard mask, according to an embodiment of the present disclosure. The structure includes an electron beam resist 302 disposed on a hard mask 304, which in turn is disposed on a substrate. As illustrated in the top portion of the figure, the exposed resist is removed selectively 312, creating an opening in the electron beam resist 302. The bottom portion of the figure illustrates the subsequent transfer of this pattern, where the pattern transfer into the hard mask 304 may occur with a non-selective physical milling process, whereas the subsequent substrate etching may occur by a chemically assisted ion etch. A liftoff process or patterning of uniformly deposited films, as in inorganic physical vapor-deposition is also possible using standard techniques, where the liftoff step uses a solvent particularly suited to the dissolution of the resist material.

Experimental lines have been successfully transferred into a 25 nm gold layer using a 200 nm Myo-inositol resist exposed with 10 nC/cm at 30 kV. 100 nm features were obtained in 400 nm grating patterns prior to careful optimization of the exposure and development processes. With a molecular size of approximately 1nm, the feature size obtainable in inositol resists has the potential to be below those obtained with other positive organic resists. The detailed mechanisms of electron beam irradiation effects still remain under investigation, but it is shown that thermally developed inositol films can be used to expose and transfer 100 nm patterns into thin metal layers using 500 V Ar ion milling.

Further process optimization may come after considering a variety of factors, including: film deposition conditions such as rate and substrate temperature relative to crystallinity and stability; underlayer adhesion to avoid gas-based delamination; within-film bubble nucleation and structure degradation; underlayer choice by etch selectivity; post-development hardening processes to reduce layer thickness while retaining transfer capabilities; diffusion and volatilization effects during development; the implications of lateral diffusion effects on pattern density; underlayer de-wetting effects during development; risk of thin feature rupture forces due to Laplace pressure during development; pattern duty-cycling and thinner layers to reduce gas build-up by outward diffusion; concurrent development while writing; implication of plasticization of adjacent unwritten areas by diffusion of scission species; effects of development environment pressure and flow rate on transport and local saturation of volatile species such that edges of regions develop faster than central regions and redeposition of mildly volatile species into unwritten areas; considerations of temperature ramping for staged selective volatilization and diffusion; effect of surface temperature during subsequent etch processing on pattern stability; effect of underlayer on lateral secondary production; sensitivity to and width of proximity effects; possibilities for de-wetting from written underlayers while maintaining adhesion to unwritten regions; and sensitivity to contaminant species acting as plasticizers After completing the pattern transfer process, the resist layer may be removed from the substrate via either wet or dry methods. A liquid cleaning procedure uses a solvent blend tailored to remove the entire resist layer and not affect other materials on the substrate. For myo-inositol, the simplest solvent is deionized water, which rapidly removes the layer. A dry or vacuum compatible resist removal method could use an oxygen plasma, which converts organic compounds into carbon dioxide and water. An alternative dry method, in cases where the material properties remain suitable, could consist of thermally evaporating the remaining material in a manner similar to that used for deposition. Vacuum-compatible resist processing and removal enables three-dimensional structures without the potentially harmful effects of surface tension from solvent-based processing techniques. Combinations of these wet or dry processes, particularly using an oxygen plasma cleaning step at the end, may improve resist residue removal if a single step process is unsatisfactory.

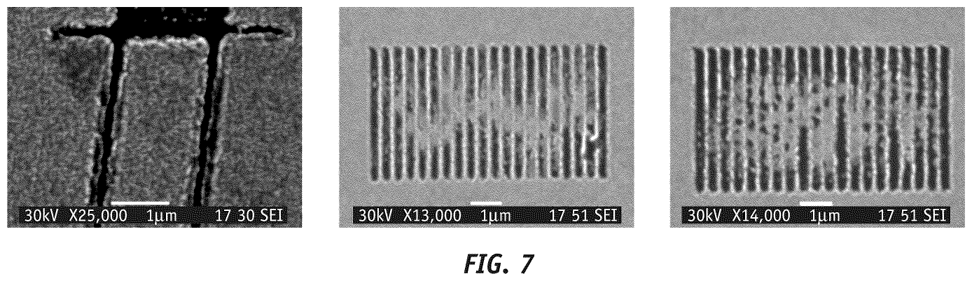

FIG. 7 shows 100 nm features fabricated by electron beam lithography with 200 nm vapor-deposited inositol resist, development by heating to 150° C. and ion milling through a platinum thin film.

Myo-inositol that has been crystallized does not show the same apparent response to electron beam exposure as an uncrystallized film. When unexposed regions are partially exposed to ambient humidity via direct evaporation of acetone in an ambient environment, the remaining material exhibits a roughened appearance under an optical microscope. When examined with an SEM, the material does not respond as layers do before crystallization, as the myo-inositol is insensitive to electron beam. On the other hand, layers that have been deposited, exposed and thermally developed do still show electron beam response during subsequent SEM exposure. This continued sensitivity demonstrates the relevance of the film properties during evaporation and subsequent processing and may lead to useful modifications in the electron beam writing process.

### Using Vacuum Processed Resists in Process Flows

In one embodiment of the process, the entire process occurs within a cluster tool vacuum environment. Within the vacuum environment, the resist is first deposited onto a substrate via evaporation. Subsequently, the resist undergoes electron beam exposure in order to define the pattern. Next, the film is heated such that the exposed regions are opened in the resist layer. Subsequently, an argon milling process may occur to etch these opening patterns into the substrate, such as a thin hard mask layer. The resist layer may then be removed at this point via oxygen plasma. The opening patterns in the hard mask may then be transferred into the underlying material of the substrate, such as silicon, via a plasma etching process. All processes may be performed without breaking the vacuum and requiring additional vacuum pumping time.

In another embodiment of the process, each step of an all-dry process may be performed in separate vacuum chambers. The resist may be deposited on the substrate in a vacuum chamber, but then removed for storage in a dry environment to minimize microstructure changes before later processing. Subsequently, the substrate may be exposed in an electron beam lithography tool. The substrate may then be developed on a hotplate in an ambient, dry, or evacuated environment. A pattern may be transferred through the developed opening into the substrate via an argon ion mill tool. The remaining resist may then be removed using a barrel oxygen plasma tool.

In another embodiment of the process, exposure and development may be combined in a single step. The resist may be deposited on the substrate in a vacuum chamber, but then removed for storage in a dry environment to minimize microstructure changes before later processing. Subsequently, the substrate may be exposed in an electron beam lithography tool in which the substrate is thermoelectrically heated to a temperature that enables simultaneous development. A pattern may be transferred through the developed opening into the substrate via an argon ion mill tool. The remaining resist may then be removed using a barrel oxygen plasma tool.

In an additional embodiment of the process, wet processing steps may be used for development and stripping. A resist layer is evaporated onto a substrate and subsequently exposed in an electron beam lithography tool. The pattern is then developed in a solution of DMSO diluted in iso-propyl alcohol (IPA). IPA is then used to rinse the developed substrate before drying with N2 gas. An oxygen plasma descum is used to clear residue at the bottom of the developed regions. A metal layer such as aluminum is then deposited using physical vapor-deposition (PVD) techniques. Liftoff and resist removal then occur by soaking in distilled water and rinsing in IPA. Resist residue may be removed with oxygen plasma.

### Exemplary Process Flows

The following exemplary process flows illustrate a summary of specific sequences of steps for lithographically patterning a substrate according to the various embodiments detailed herein. These flows consolidate the steps of the distinct methods described above, specifically regarding the sequential dry process, the simultaneous exposure and development process, and the solvent-based development process, to provide a clear overview of the operational sequences.

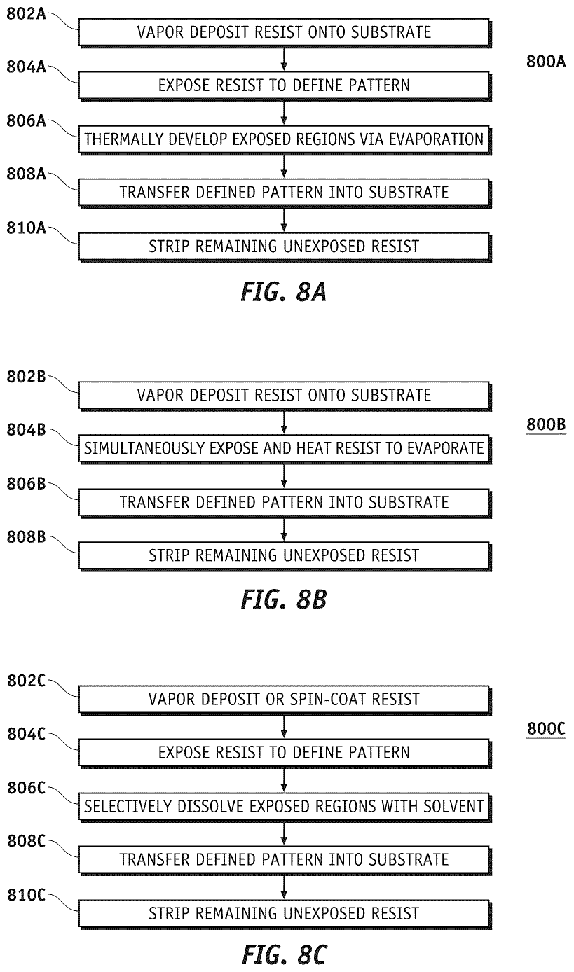

FIG. 8A shows a flowchart of a sequential dry lithography process 800A, according to an embodiment of the present disclosure. Here are the preferred steps of the process:
Step 802A: Vapor-depositing a resist layer onto a substrate.
Step 804A: Exposing at least a portion of the resist layer with a particle beam to define a pattern, thereby creating exposed regions and unexposed regions in the resist layer.
Step 806A: Thermally developing the exposed regions of the resist layer by heating the resist layer to a temperature and for a duration that causes the exposed regions to be removed via evaporation, thereby defining the pattern in the resist layer by retaining the unexposed regions.
Step 808A: Transferring the defined pattern from the resist layer into the substrate.
Step 810A: Stripping the remaining unexposed regions of the resist layer using a chemical or thermal process, the stripping occurring after the pattern transferring step.

FIG. 8B shows a flowchart of a simultaneous exposure and development process 800B, according to an embodiment of the present disclosure.
Step 802B: Vapor-depositing a resist layer onto a substrate.
Step 804B: Exposing at least a portion of the resist layer with a particle beam to define a pattern while simultaneously heating the resist layer to a temperature that causes material in exposed regions of the resist layer to leave the exposed regions via evaporation, thereby defining the pattern in the resist layer by retaining unexposed regions.
Step 806B: Transferring the defined pattern from the resist layer into the substrate.
Step 808B: Stripping the remaining unexposed regions of the resist layer using a chemical or thermal process, the stripping occurring after the pattern transferring step.

FIG. 8C shows a flowchart of a solvent-based lithography process 800C, according to an embodiment of the present disclosure.
Step 802C: Vapor-depositing a resist layer onto a substrate (or alternatively spin-coating from water).
Step 804C: Exposing at least a portion of the resist layer with a particle beam to define a pattern, thereby creating exposed regions and unexposed regions in the resist layer.
Step 806C: Developing the exposed regions of the resist layer using a solvent that selectively dissolves the exposed regions while substantially maintaining the unexposed regions, thereby defining the pattern in the resist layer.
Step 808C: Transferring the defined pattern from the resist layer into the substrate.
Step 810C: Stripping the remaining unexposed regions of the resist layer using a chemical or thermal process (e.g., deionized water), the stripping occurring after the pattern transferring step.

The described embodiments should not be taken exclusively and other embodiments will be apparent to those familiar in the art. The precise sequence of the steps is known to have flexibility to those familiar in the art in response to the particular process and requirements.

A number of embodiments of the disclosure have been described. Nevertheless, it will be understood that various modifications may be made without departing from the spirit and scope of the present disclosure. Accordingly, other embodiments are within the scope of the following claims.

The examples set forth above are provided to those of ordinary skill in the art as a complete disclosure and description of how to make and use the embodiments of the disclosure and are not intended to limit the scope of what the inventor/inventors regard as their disclosure.

Modifications of the above-described modes for carrying out the methods and systems herein disclosed that are obvious to persons of skill in the art are intended to be within the scope of the following claims. All patents and publications mentioned in the specification are indicative of the levels of skill of those skilled in the art to which the disclosure pertains. All references cited in this disclosure are incorporated by reference to the same extent as if each reference had been incorporated by reference in its entirety individually.

It is to be understood that the disclosure is not limited to particular methods or systems, which can, of course, vary. It is also to be understood that the terminology used herein is for the purpose of describing particular embodiments only and is not intended to be limiting. As used in this specification and the appended claims, the singular forms “a,” “an,” and “the” include plural referents unless the content clearly dictates otherwise. The term “plurality” includes two or more referents unless the content clearly dictates otherwise. Unless defined otherwise, all technical and scientific terms used herein have the same meaning as commonly understood by one of ordinary skill in the art to which the disclosure pertains.

1. A process for lithographically patterning a substrate in a positive polarity, the process comprising:
(a) vapor-depositing a resist layer onto the substrate;
(b) exposing at least a portion of the resist layer with a particle beam to define a pattern, thereby creating exposed regions and unexposed regions in the resist layer;
(c) thermally developing the exposed regions of the resist layer by heating the layer to a temperature and for a duration that causes the exposed regions to be removed via evaporation, thereby defining the pattern in the resist layer by retaining the unexposed regions;
(d) transferring the defined pattern from the resist layer into the substrate; and
(e) stripping the remaining unexposed regions of the resist layer using a chemical or thermal process, the stripping occurring after the pattern transferring step (d).

2. The process of claim 1, wherein the physically vapor-depositing step (a), the exposing step (b), and the thermally developing step (c) are performed in a vacuum environment.

3. The process of claim 2, wherein the transferring step (d) and the stripping step (e) are performed in the vacuum environment.

4. The process of claim 1, wherein the resist layer comprises an organic material.

5. The process of claim 4, wherein the organic material is selected such that the resist layer maintains a stable structure after deposition.

6. The process of claim 4, wherein the organic material comprises a polyol.

7. The process of claim 6, wherein the polyol is a sugar alcohol.

8. The process of claim 7, wherein the sugar alcohol is myo-inositol.

9. The process of claim 1, wherein the thermally developing step (c) is performed at a temperature between 75° C. and 150° C.

10-13. (canceled)

14. The process of claim 1, wherein the stripping step (e) comprises at least one of: heating the resist layer to a temperature above 200° C. or exposing the resist layer to an oxygen plasma.

15. (canceled)

16. A process for lithographically patterning a substrate in a positive polarity, the process comprising:
(a) physically vapor-depositing a resist layer onto the substrate;
(b) exposing at least a portion of the resist layer with a particle beam to define a pattern while simultaneously heating the resist layer to a temperature that causes material in exposed regions of the resist layer to leave the exposed regions via evaporation, thereby defining the pattern in the resist layer by retaining unexposed regions;
(c) transferring the defined pattern from the resist layer into the substrate; and
(d) stripping the remaining unexposed regions of the resist layer using a chemical or thermal process, the stripping occurring after the pattern transferring step (c).

17. The process of claim 16, wherein the heating in step (b) is performed by at least one of: resistive heating, thermoelectric heating, infrared radiation, or a focused laser beam.

18. The process of claim 16, wherein the heating in step (b) utilizes a high energy state of molecules of the resist layer while impacted by the particle beam to enable volatilization at a lower temperature compared to sequential exposure and development.

19. The process of claim 16, wherein the resist layer comprises a sugar alcohol.

20. The process of claim 19, wherein the sugar alcohol is myo-inositol.

21. A process for lithographically patterning a substrate in a positive polarity, the process comprising:
(a) vapor-depositing a resist layer onto the substrate;
(b) exposing at least a portion of the resist layer with a particle beam to define a pattern, thereby creating exposed regions and unexposed regions in the resist layer;
(c) developing the exposed regions of the resist layer using a solvent that selectively dissolves the exposed regions while substantially maintaining the unexposed regions, thereby defining the pattern in the resist layer;
(d) transferring the defined pattern from the resist layer into the substrate; and
(e) stripping the remaining unexposed regions of the resist layer using a chemical or thermal process, the stripping occurring after the pattern transferring step (d).

22. The process of claim 21, wherein the solvent comprises a polar, non-protic solvent.

23. The process of claim 22, wherein the polar, non-protic solvent is selected from the group including: dimethylacetamide, dimethylformamide, n-methyl-2-pyrrolidone, and dimethyl sulfoxide.

24. The process of claim 21, wherein the developing step (c) utilizes a solvent diluted with a non-interacting solvent to control a development rate.

25. (canceled)

26. The process of claim 21, wherein the stripping step (e) comprises using deionized water to remove the resist layer.

27-38. (canceled)
